(19) United States
(12) Patent Application Publication
(10) Pub. No.: US 2016/0021318 A1
(43) Pub. Date: Jan. 21, 2016

(54) IMAGE SENSOR

(71) Applicant: Samsung Electronics Co., Ltd., Suwon-si (KR)

(72) Inventors: Hyeok Jong LEE, Seongnam-si (KR); Sung Ho SUH, Hwaseong-si (KR); Young Tae JANG, Pyeongtaek-si (KR); Jin Ho SEO, Seoul (KR)

(21) Appl. No.: 14/669,261

(22) Filed: Mar. 26, 2015

(30) Foreign Application Priority Data
Jul. 15, 2014 (KR) 10-2014-0089241

(51) Int. Cl. H04N 5/363; H01L 27/146; H04N 5/374; H04N 5/3745; H04N 3/14; H04N 5/378

(52) U.S. Cl. CPC H04N 5/363; H04N 3/155; H04N 5/378; H04N 5/3742; H04N 5/37455; H01L 27/14609

(57) ABSTRACT

An image sensor includes a comparator configured to compare a pixel signal with a ramp signal and generate a comparison signal and a counter configured to be reset by a counter reset value based on an offset of the comparator and to generate a digital pixel signal according to the comparison signal.

### CROSS-REFERENCE TO RELATED APPLICATIONS

This application claims priority under 35 U.S.C. §119(a) from Korean Patent Application No. 10-2014-0089241 filed on Jul. 15, 2014, the disclosure of which is hereby incorporated by reference in its entirety.

### BACKGROUND

Example embodiments relate to an image sensor. For example, at least some example embodiments relate to an image sensor for more efficiently removing noise from image data.

Complementary metal oxide semiconductor (CMOS) image sensors are solid state image sensing devices using CMOS. CMOS image sensors may have lower manufacturing cost and/or smaller size than charge coupled device (CCD) image sensors including a high-voltage analog circuit and thus may have an advantage of lower power consumption. In addition, the performance of CMOS image sensors has been improved as compared to their early development stage, and therefore, CMOS image sensors are usually used for various electronic appliances including portable devices such as smart phones and digital cameras.

There has been a lot of research into increasing the quality of images generated in CMOS image sensors. For example, image quality may be deteriorated by various kinds of noise occurring in internal elements of CMOS image sensors during operation.

### SUMMARY

Some example embodiments of the inventive concepts relate to an image sensor for increasing the quality of images by efficiently removing noise occurring therewithin.

According to some example embodiments of the inventive concepts, the image sensor may include a comparator configured to compare a pixel signal with a ramp signal and generate a comparison signal and a counter configured to be reset by a counter reset value based on an offset of the comparator and to generate a digital pixel signal according to the comparison signal.

The image sensor may further include a counter setting unit configured to generate the counter reset value using a digital reset signal generated using a predetermined reference signal as an input of the comparator.

The counter setting unit may include a counter reset memory configured to store the counter reset value.

The counter setting unit may further include a filter configured to perform filtering on the digital reset signal generated repeatedly.

The filter may be an infinite impulse response (IIR) filter.

According to other example embodiments of the inventive concepts, there is provided an image processing system including the image sensor and an image processor configured to perform an operation of on the digital pixel signal and a digital value corresponding to the reference signal.

The counter reset value may be updated at a predetermined (or alternatively, desired) interval.

According to other embodiments of the inventive concepts, there is provided an image sensor including a plurality of comparators each configured to compare one of pixel signals corresponding to first through m-th columns included in a pixel array with a ramp signal and generate a comparison signal, where “m” is an integer of at least 2; and a plurality of counters each configured to be reset by a counter reset value based on an offset of a corresponding one of the comparators and to generate a digital pixel signal according to the comparison signal. A counter reset value input to one of the counters may be different from a counter reset value input to another one of the counters.

The image sensor may further include a counter setting unit configured to generate the counter reset value using a digital reset signal generated using a predetermined reference signal as an input of the comparator.

The counter setting unit may include a counter reset memory configured to store the counter reset value.

In some example embodiments, the image sensor may include a pixel array configured to output a pixel signal from a column thereof; and an analog-to-digital converter (ADC).

The ADC may include a comparator configured to generate a comparison signal indicating which of an input signal and a ramp signal is greater, a counter configured to generate a count based on the comparison signal, and to adjust the count based on an offset of the comparator determined while the input signal to the comparator is a reference signal, and at least one switch configured to selectively output one of the reference signal and the pixel signal as the input signal to the comparator.

### BRIEF DESCRIPTION OF THE DRAWINGS

The above and other features and advantages of example embodiments of the inventive concepts will become more apparent by describing in detail some example embodiments thereof with reference to the attached drawings in which:

FIG. 1 is a block diagram of an image processing system including an image sensor according to some example embodiments of the inventive concepts;

FIG. 2 is a detailed diagram of an example of the image sensor illustrated in FIG. 1;

FIGS. 3A through 3E are circuit diagrams of examples of a pixel illustrated in FIG. 2;

FIG. 4 is a detailed diagram of an example of a input control unit illustrated in FIG. 2;

FIG. 5 is a detailed diagram of an example of a counter setting unit illustrated in FIG. 2;

FIG. 6 is an example of a diagram for explaining the operation of the image sensor illustrated in FIG. 2;

FIG. 7 is a block diagram of an electronic system including an image sensor according to some example embodiments of the inventive concepts; and

FIG. 8 is a block diagram of an image processing system including an image sensor according to other example embodiments of the inventive concepts.

### DETAILED DESCRIPTION OF EXAMPLE EMBODIMENTS

Example embodiments of the inventive concepts now will be described more fully hereinafter with reference to the accompanying drawings, in which some example embodiments are shown. These example embodiments may, however, be embodied in many different forms and should not be construed as limited to the example embodiments set forth herein. Rather, these example embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular example embodiments only and is not intended to be limiting thereof. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

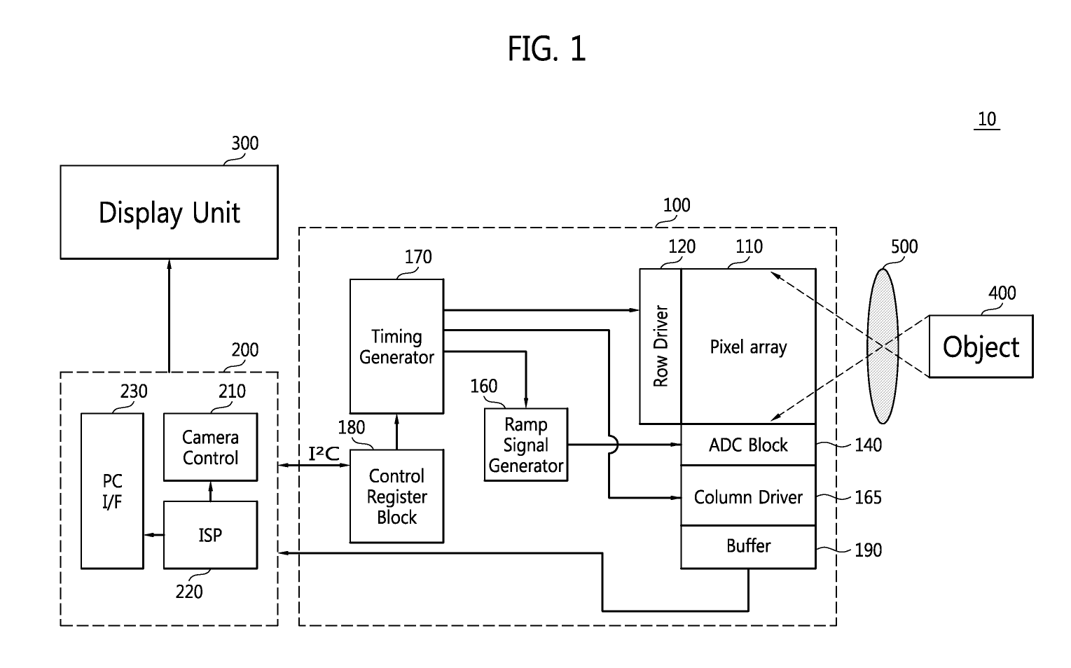

FIG. 1 is a block diagram of an image processing system 10 including an image sensor 100 according to some example embodiments of the inventive concepts.

Referring to FIG. 1, the image processing system 10 may include the image sensor 100, a digital signal processor (DSP) 200, a display unit 300, and/or a lens 500.

The image sensor 100 includes a pixel array 110, a row driver 120, an analog-to-digital converter (ADC) block 140, a ramp signal generator 160, a column driver 165, a timing generator 170, a control register block 180, and/or a buffer 190.

The image sensor 100 may be controlled by the DSP 200 to sense an object 400 captured through the lens 500. The DSP 200 may output an image, which has been sensed and output by the image sensor 100, to the display unit 300. The display unit 300 may be any device that can output an image. For instance, the display unit 300 may be implemented as a computer, a mobile phone, or an electronic device equipped with a camera.

The DSP 200 may include a camera control 210, an image signal processor (ISP) 220, and/or a personal computer interface (PC I/F) 230. The camera control 210 controls the control register block 180. The camera control 210 may control the image sensor 100, and more specifically, the control register block 180 using an inter-integrated circuit (I²C), but the scope of the example embodiments of the inventive concepts are not restricted thereto.

The ISP 220 receives image data, i.e., an output signal of the buffer 190, performs image processing on the image data to generate an image, and outputs the image to the display unit 300 through the PC I/F 230. While FIG. 1 illustrates that the ISP 220 is positioned within the DSP 200, example embodiments are not limited thereto. For instance, the ISP 220 may be positioned within the image sensor 100.

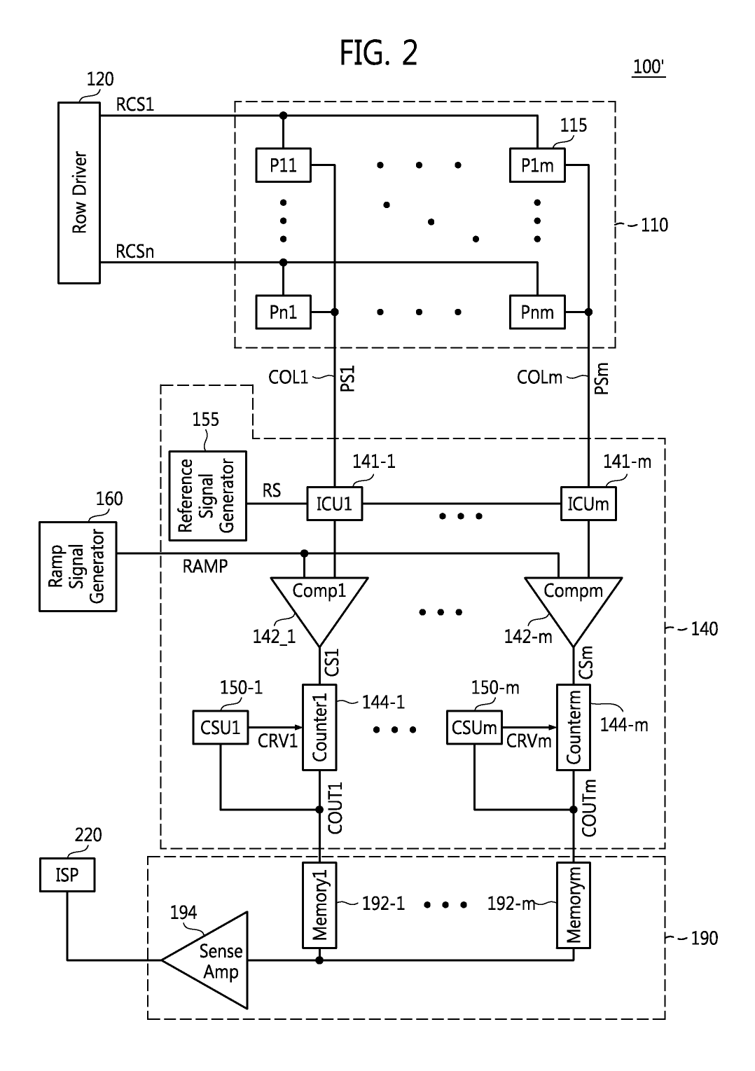

The pixel array 110 includes a plurality of pixels (115 in FIG. 2) each of which includes a photoelectric conversion element such as a photo diode or a pinned photo diode. Each pixel 115 senses light using the photoelectric conversion element and converts the light into an electrical signal, thereby generating an image signal.

The timing generator 170 may output a control signal or a clock signal to the row driver 120, the ramp signal generator 160, and the column driver 165 to control the operation or timing of the row driver 120, the ramp signal generator 160, and the column driver 165. The control register block 180 may transmit a control signal or a clock signal from the DSP 200 to the timing generator 170.

The row driver 120 drives the pixel array 110 in units of rows. The row driver 120 may generate control signals (RCS1 through RCSn in FIG. 2) for controlling the pixels 115 forming the pixel array 110. The pixel array 110 outputs a pixel signal PS, i.e., a reset signal and the image signal (among pixel signals PS1 through PSm in FIG. 2) from a row elected by the control signals RCS1 through RCSn of the row driver 120 to the ADC block 140.

The ADC block 140 compares a ramp signal (RAMP in FIG. 2) received from the ramp signal generator 160 with the pixel signals PS1 through PSm received from the pixel array 110 to generate comparison signals (CS1 through CSm in FIG. 2) and performs counting on the comparison signals CS1 through CSm to output digital pixel signals (COUT1 through COUTm in FIG. 2) to the buffer 190.

The column driver 165 may control the operation of the ADC block 140 and the buffer 190 according to the control of the timing generator 170. In detail, the column driver 165 may control the timing at which a digital pixel signal per column in the pixel array 110 is generated and output. The buffer 190 temporarily stores the counter output signals COUT1 through COUTm output from the ADC block 140 and then senses, amplifies and outputs the counter output signals COUT1 through COUTm.

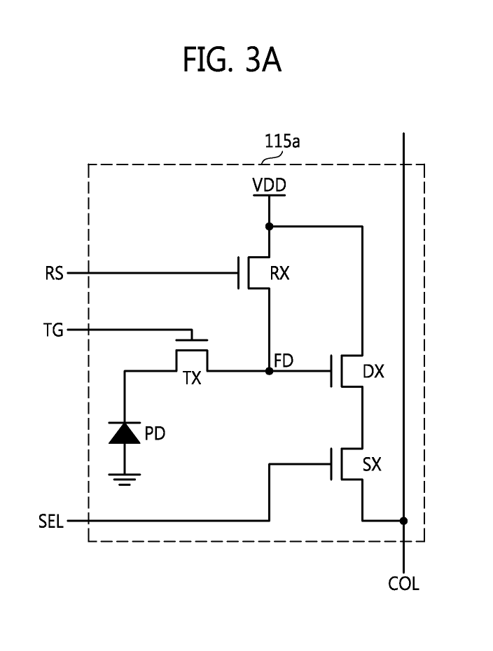

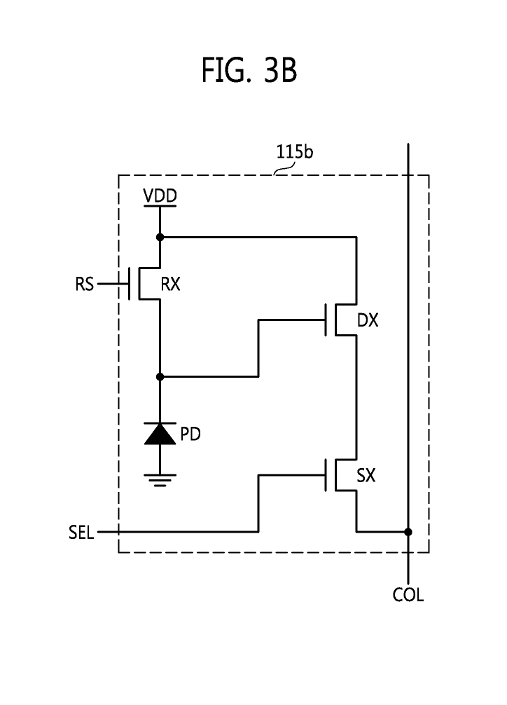

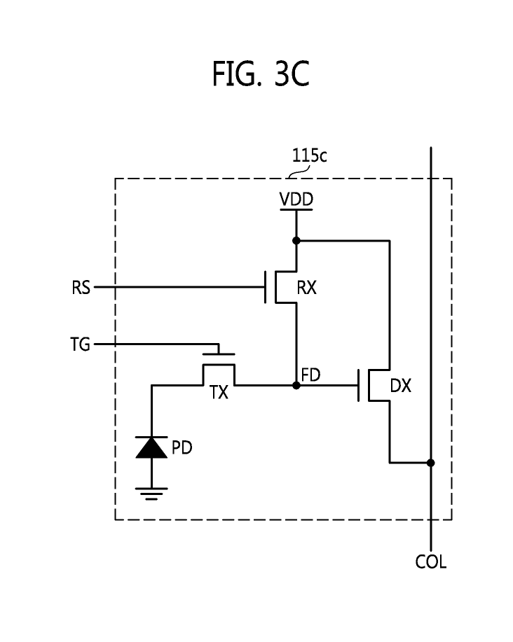

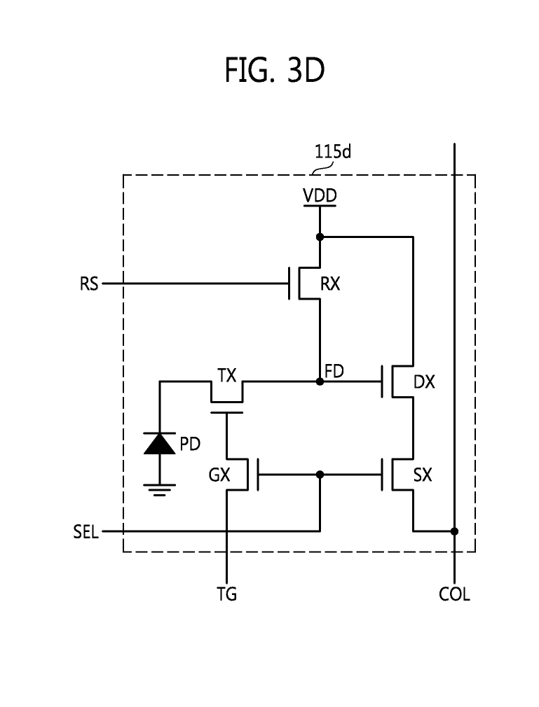

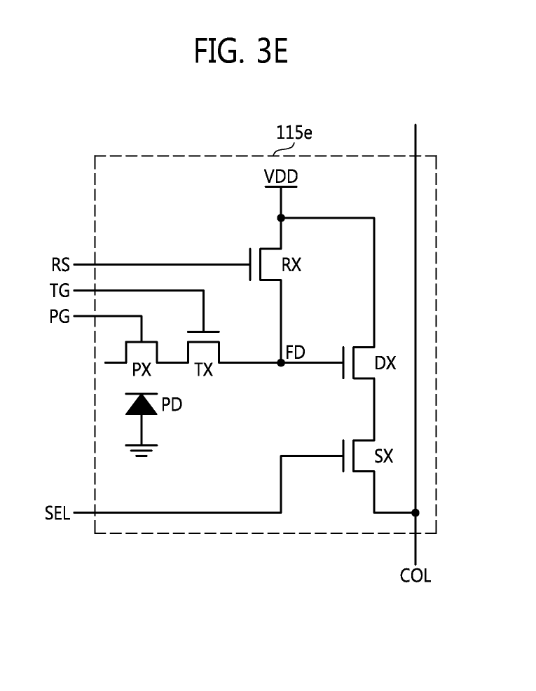

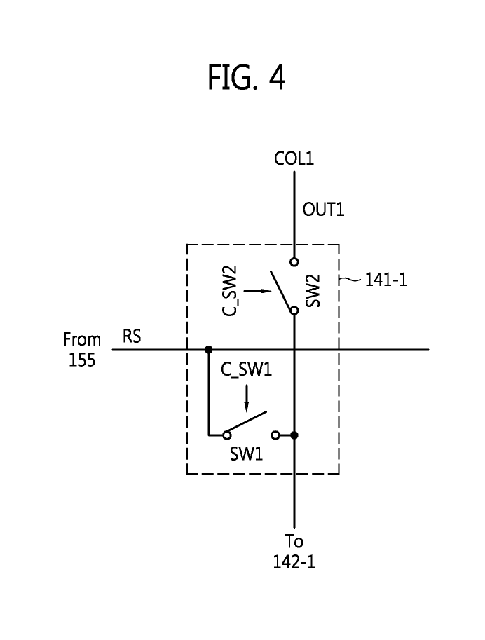

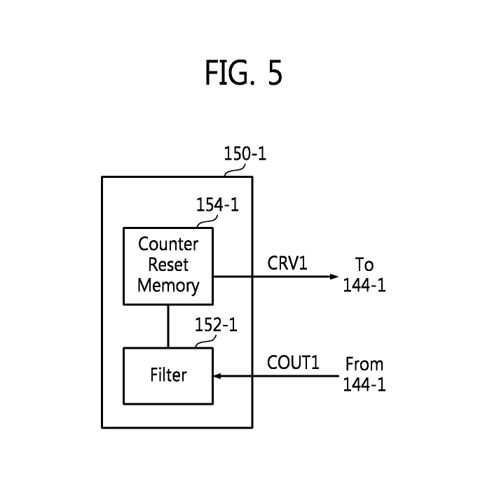

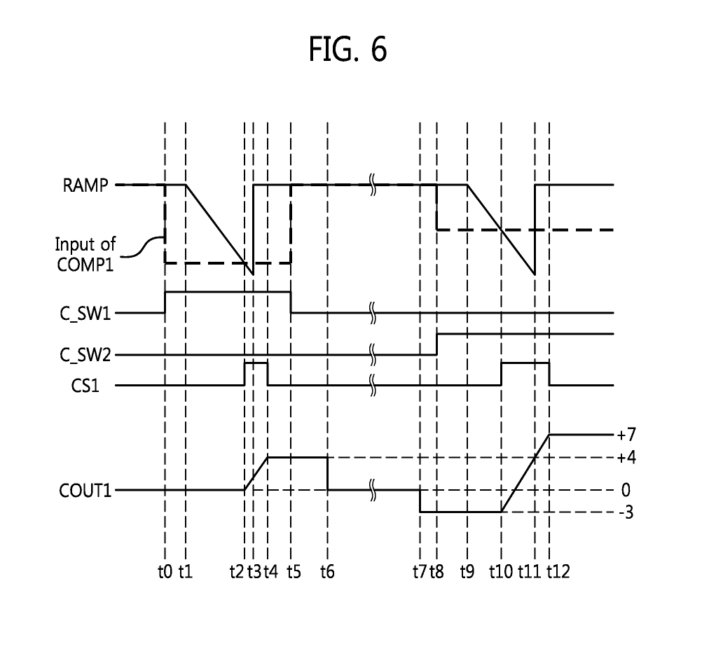

FIG. 2 is a detailed diagram of an example 100′ of the image sensor 100 illustrated in FIG. 1. FIGS. 3A through 3E are circuit diagrams of examples 115a, 115b, 115c, 115d, and 115e of a pixel 115 illustrated in FIG. 2. FIG. 4 is a detailed diagram of an input control unit (ICU) 141-1 illustrated in FIG. 2. FIG. 5 is a detailed diagram of a counter setting unit (CSU) 150-1 illustrated in FIG. 2. FIG. 6 is a diagram for explaining the operation of the image sensor 100′ illustrated in FIG. 2.

Referring to FIGS. 1 through 6, the image sensor 100′ shown in FIG. 2 is a part of the image sensor 100 and is provided to describe the operations of the image sensor 100 illustrated in FIG. 1.

The image sensor 100′ may include the pixel array 110, the row driver 120, the ADC block 140, the ramp signal generator 160, and/or the buffer 190.

The pixel array 110 may include a plurality of the pixels P11 through Pnm or 115 connected to a plurality of row lines and column lines COL1 through COLm.

The pixel array 110 may be formed by vertically stacking a semiconductor substrate (not shown), an interlayer insulation layer (not shown), a color filter layer (not shown), and microlenses (not shown). The semiconductor substrate may be formed by forming a p-type epitaxial layer on a p-type bulk silicon substrate. A photodiode (not shown) may be formed by implanting n-type ions into the p-type epitaxial layer. The interlayer insulation layer may be formed on the semiconductor substrate. The interlayer insulation layer may include gates of transistors forming a pixel and multi-layer conductive lines. A protective layer (not shown) may be formed on the interlayer insulation layer to protect elements. The color filter layer may be formed on the interlayer insulation layer (or the protective layer) and may include a plurality of color filters (not shown). Bayer pattern technology may be applied to the color filter layer. For instance, color filters may include at least one red filter, at least one green filter, and at least one blue filter or may include at least one magenta filter, at least one cyan filter, and at least one yellow filter. A planarization layer called an over-coating layer may be formed on the color filter layer. The microlenses are formed on the color filter layer (or the planarization layer) to efficiently guide incident light to the photodiode of the pixel.

The pixels 115 may include active pixels and line-optical black (L-OB) pixels.

The active pixels may generate an electrical signal corresponding to photocharges varying with the intensity of incident light.

In the L-OB pixels, a photodiode may be removed or a shield layer may be formed on a layer corresponding to a color filter. Therefore, the L-OB pixels may generate signals according to noise regardless of incident light. For example, the L-OB pixel may generate a dark level offset signal containing row noise.

The ISP 220 may remove the row noise detected by the line-optical black L-OB pixels 115 from the output signals of the active pixels 115 using auto dark level compensation (ADLC) technology.

The pixels 115 may be sequentially activated in response to the row control signals RCS1 through RCSn received from the row driver 120 and may output the output signals PS1 through PSm to the respective column lines COL1 through COLm.

Examples of each of the pixels 115 are illustrated in FIGS. 3A through 3E. It is assumed that the pixels 115a through 115e illustrated in FIGS. 3A through 3E are active pixels, but they may be L-OB pixels, with the exception that a photodiode PD may be removed. A reset control signal RS, a transfer control signal TG, a select control signal SEL, or a photo gate signal PG may be included one of the row control signals RCS1 through RCSn.

Referring to FIG. 3A, a pixel 115a may include a photodiode PD, a transfer transistor TX, a floating sensing node FD, a reset transistor RX, a drive transistor DX, and a select transistor SX. The photodiode PD is an example of a photoelectric conversion element and may include at least one among a photo transistor, a photo gate, a pinned photodiode (PPD), and a combination thereof.

FIG. 3A shows a 4-transistor (4T) structure that includes one photodiode PD and four metal oxide semiconductor (MOS) transistors TX, RX, DX, and SX, but example embodiments of the inventive concepts are not restricted to this example. For example, any circuits including at least three transistors including the drive transistor DX and the select transistor SX and the photodiode PD may be used in the embodiments of the inventive concepts.

In the operation of the pixel 115a, the photodiode PD holds photocharges generated according to the intensity of light from the object 400. The transfer transistor TX may transfer the photocharges to the floating diffusion node FD in response to the transfer control signal TG received from the row driver 120. The drive transistor DX may amplify and transmit the photocharges to the select transistor SX according to potential arising from the photocharges accumulated at the floating diffusion node FD.

The select transistor SX has a drain terminal connected to a source terminal of the drive transistor DX. The select transistor SX may output an output signal to a column line COL connected to the pixel 115a in response to the select control signal SEL received from the row driver 120. The column line COL is one among the column lines COL1 through COLm illustrated in FIG. 2. The output signal transmitted to the column line COL is one among the pixel signals PS1 through PSm illustrated in FIG. 2.

The reset transistor RX may reset the floating diffusion node FD to a power supply voltage VDD in response to the reset control signal RS received from the row driver 120. The output signal output by the selection transistor SX to the column line COL may be either a reset signal or an image signal. For example, the output signal from the select transistor SX may be the reset when the floating diffusion node FD is reset to the power supply voltage VDD by the reset transistor RX. Further, the output signal from the select transistor SX may be the image signal after transfer of photocharges from the transfer transistor TX to the floating diffusion node FD is completed. The pixel 115a may sequentially output the reset signal and the image signal as the output signal according to the control of the row driver 120.

Other examples of the pixel 115 are illustrated in FIGS. 3B through 3E.

Referring to FIG. 3B, a pixel 115b is a unit pixel having a 3-transistor (3T) structure. The pixel 115b may include the photodiode PD, the reset transistor RX, the drive transistor DX, and the select transistor SX. Photocharges generated by the photodiode PD may be accumulated at the floating diffusion node FD. An output signal may be output to the column line COL according to the operations of the drive transistor DX and the select transistor SX.

Referring to FIG. 3C, a pixel 115c is a unit pixel having a 3T structure. The pixel 115c may include the photodiode PD, the transfer transistor TX, the reset transistor RX, and the drive transistor DX. The reset transistor RX may be implemented as an n-channel depression type transistor. The reset transistor RX may reset the floating diffusion node FD to the power supply voltage VDD according to the reset control signal RS output from the row driver 120 and/or may perform a similar function to that of the select transistor SX by setting the floating diffusion node FD to a low level (e.g., 0 V).

Referring to FIG. 3D, a pixel 115d is a unit pixel having a 5-transistor (5T) structure. The pixel 115d includes the photodiode PD, the transfer transistor TX, the reset transistor RX, the drive transistor DX, the select transistor SX, and another transistor GX.

Referring to FIG. 3E, a pixel 115e is a 5T unit pixel which includes the photodiode PD, the transfer transistor TX, the reset transistor RX, the drive transistor DX, the select transistor SX, and a photo transistor PX. The photo transistor PX outputs photocharges to the transfer transistor TX according to the photo gate signal PG output from the row driver 120.

Referring back to FIG. 2, the row driver 120 may select at least one of the row lines in the pixel array 110 using the row control signals RCS1 through RCSn.

The analog-to-digital converter (ADC) block 140 may include first through m-th ICUs 141-1 through 141-m, first through m-th comparators 142-1 through 142-m, first through m-th counters 144-1 through 144-m, first through m-th CSUs 150-1 through 150-m, and a reference signal generator 155.

The first through m-th input control unit (ICUs) 141-1 through 141-m are connected to the first through m-th column lines COL1 through COLm, respectively. For example, the pixel signals PS may be provided to the ICUs 141-1 through 141-m via respective ones of the column lines COL1 through COLm

FIG. 4 shows the first ICU 141-1 among the first through m-th ICUs 141-1 through 141-m. The structure and operations of the remaining input control units 141-2 through 141-m are substantially the same as those of the first ICU 141-1.

Referring to FIG. 4, the first ICU 141-1 may include a first switch SW1 and/or a second switch SW2.

The first switch SW1 is connected between the reference signal generator 155 and the first comparator 142-1. The first switch SW1 may operate in response to a first switch control signal C_SW1. When the first switch control signal C_SW1 is at a high level (e.g., a logic level of “1”), the first switch SW1 is short-circuited, so that a reference signal RS of the reference signal generator 155 can be input to the first comparator 142-1. When the first switch control signal C_SW1 is at a low level (e.g., a logic level of “0”), the first switch SW1 is opened, so that the reference signal RS of the reference signal generator 155 cannot be input to the first comparator 142-1.

The second switch SW2 is connected between the first column line COL1 and the first comparator 142-1. The second switch SW2 may operate in response to a second switch control signal C_SW2. When the second switch control signal C_SW2 is at a high level (e.g., a logic level of “1”), the second switch SW2 is short-circuited, so that the first pixel signal PS1 of the first column line COL1 can be input to the first comparator 142-1. When the second switch control signal C_SW2 is at a low level (e.g., a logic level of “0”), the second switch SW2 is opened, so that the first pixel signal PS1 of the first column line COL1 cannot be input to the first comparator 142-1.

The first and second switch control signals C_SW1 and C_SW2 may be received from the timing generator 170, but example embodiments of the inventive concepts are not restricted to the current example embodiments. For example, the switch control signals C_SW1 and C_SW2 may be received from the column driver 165 in other example embodiments.

Referring back to FIG. 2, the pixel array 110 and the ADC block 140 may operate in analog correlated double sampling (CDS) mode in which offsets of the pixels P11 through Pnm are removed using capacitors (not shown) and switches (not shown) specially provided at the input ports of the first through m-th comparators 142-1 through 142-m, but the detailed description thereof will be omitted here. It is assumed that the pixel signals PS1 through PSm are obtained after pixel noise (e.g., reset noise) is removed in analog CDS mode.

The first through m-th comparators 142-1 through 142-m may receive the first through m-th pixel signals PS1 through PSm, respectively, from the first through m-th ICUs 141-1 through 141-m, respectively. Each of the first through m-th comparators 142-1 through 142-m may receive as an input to a first terminal thereof either the reference signal RS or one of the pixel signals PS1 through PSm. Further, each of the first through m-th comparators 142-1 through 142-m may receive a ramp signal as an input to a second terminal thereof.

Each of the first through m-th comparators 142-1 through 142-m may compare the ramp signal RAMP from the ramp signal generator 160 with one of the first through m-th pixel signals PS1 through PSm or the reference signal RS and may generate one of the first through m-th comparison signals CS1 through CSm according to the comparison result.

The first through m-th counters 144-1 through 144-m may perform counting on the first through m-th comparison signals CS1 through CSm, respectively, received from the first through m-th comparators 142-1 through 142-m respectively connected with the first through m-th counters 144-1 through 144-m to generate first through m-th counter output signals COUT1 through COUTm, respectively. The first through m-th counter output signals COUT1 through COUTm are digital pixel signals or digital reset signals respectively corresponding to the column lines COL1 through COLm in the pixel array and may be transmitted to the first through m-th CSUs 150-1 through 150-m, respectively, and to the buffer 190.

The first through m-th CSUs 150-1 through 150-m may generate counter reset values CRV1 through CRVm, respectively, using the digital reset signals respectively received from the first through m-th counters 144-1 through 144-m. The first through m-th counters 144-1 through 144-m may be reset by the counter reset values CRV1 through CRVm, respectively. The digital reset signals are the first through m-th counter output signals COUT1 through COUTm generated when the reference signal RS generated by the reference signal generator 155 is the input of the first through m-th comparators 142-1 through 142-m.

The reference signal generator 155 may provide the reference signal RS for the first through m-th comparators 142-1 through 142-m. For instance, the reference signal generator 155 may generate the reference signal RS which is lower than the ramp signal RAMP during a desired (or, alternatively, a predetermined) period to allow a digital value generated using the reference signal RS to be a desired (or, alternatively, a predetermined) value. However, the example embodiments of the inventive concepts are not restricted to the current example embodiments.

FIG. 5 shows the first CSU 150-1 among the first through m-th CSUs 150-1 through 150-m. The structure and operations of the second through m-th CSUs 150-2 through 150-m are substantially the same as those of the first CSU 150-1. Thus, the structure and operations of the first CSU 150-1 only will be described to avoid redundancy.

Referring to FIG. 5, the first CSU 150-1 may include a filter 152-1 and/or a counter reset memory 154-1.

The filter 152-1 may repeatedly perform filtering on a digital reset signal.

When the output COUT of the counter 144 is the digital reset signal generated using the reference signal RS as the input to the second terminal of the comparator 142_1, the digital reset signal may include digital values respectively corresponding to the reference signal RS, an offset of the comparator 142-1, and extra noise.

The offset of the first through m-th comparators 142-1 through 142-m may be due to noise occurring therein. Even if the first through m-th comparators 142-1 through 142-m have the same structure, an offset may occur among the first through m-th comparators 142-1 through 142-m due to a difference in manufacturing processes therebetween.

The offset of the first through m-th comparators 142-1 through 142-m is included in the output of the first through m-th comparators 142-1 through 142-m. The offset may be constant in each of the first through m-th comparators 142-1 through 142-m and may be different among columns. Due to the offset of the first through m-th comparators 142-1 through 142-m which is constant by columns, a final image may have a fitted pattern noise (FPN) in a column direction.

In addition to the noise causing the offset in the first through m-th comparators 142-1 through 142-m, extra noise may occur due to factors other than the offset of the first through m-th comparators 142-1 through 142-m. For example, the extra noise may be due to instability of power supplied to the ADC block 140 and noise occurring during transmission of signals.

Unlike the offset, which may be constant, the extra noise may be variable over time. A digital value corresponding to the extra noise is random around “0”.

When the digital reset signal includes the digital values respectively corresponding to the reference signal RS, the offset of the comparator 142-1, and the extra noise and is generated three times, it may be expressed by Equations 1 through 3:

DRS1_{—}D=RS1_{—}D+OFFSET1_{—}D+RN1_{—}D, (1)

DRS2_{—}D=RS2_{—}D+OFFSET2_{—}D+RN2_{—}D, and (2)

DRS3_{—}D=RS3_{—}D+OFFSET3_{—}D+RN3_{—}D, (3)

wherein DRS1_D, DRS2_D, and DRS3_D denote digital reset signals sequentially generated as the output COUT of the counter 144 at first through third times; RS1_D, RS2_D, and RS3_D denote digital values corresponding to the reference signal RS input to the second terminal of the comparator 142-1 at first through third times, respectively; OFFSET1_D, OFFSET2_D, and OFFSET3_D denote digital values corresponding to the offset of the comparator 142-1 generated at first through third times, respectively; and RN1_D, RN2_D, and RN3_D denote digital values included in respective ones of the digital reset signals DRS1_D, DRS2_D, and DRS3_D output by the counter 144 corresponding to the extra noise generated at first through third times, respectively. At this time, when it is assumed that the reference signal RS is always lower than the ramp signal RAMP, the digital values RS1_D, RS2_D, and RS3_D are all zeros.

The filter 152-1 may perform an operation of sequentially adding the digital reset signals DRS1_D through DRS3_D generated through repetitive three times of filtering and then dividing by 3. A result of adding the digital reset signals DRS1_D through DRS3_D is the same as a value obtained by adding the sum of the digital values OFFSET1_D through OFFSET3_D and the sum of the digital values RN1_D through RN3_D.

As discussed above, the offset may be constant, and, therefore, the digital values OFFSET1_D through OFFSET3_D are all the same (as a value of OFFSET1_D). Further, while the extra noise is random, the digital values RN1_D through RN3_D corresponding to the extra noise are randomly distributed around zero, and, therefore, the sum of the digital values RN1_D through RN3_D may be close to 0.

Therefore, it could be construed that the sum of the digital values RN1_D through RN3_D converges to 0 when the digital reset signal is generated repeatedly a sufficient number of times. When it is assumed that the sum of the digital values RN1_D through RN3_D is 0, the result of adding the digital reset signals DRS1_D through DRS3_D is 3*OFFSET1_D and a result of dividing 3*OFFSET1_D by 3 is the digital value OFFSET1_D corresponding to the offset of the comparator 142-1 only.

The above-described filtering method used by the filter 152-1 is just an example. The filter 152-1 may be an infinite impulse response filter in other embodiments.

In other words, the filter 152-1 may generate the counter reset value CRV1, i.e., a digital value corresponding to only the offset of the comparator 142-1 (including the reference signal RS when a digital value obtained using the reference signal RS is not 0) with extra noise removed by performing filtering on a digital reset signal repeatedly.

In addition, the filter 152-1 may also store a digital value corresponding to the reference signal RS and may generate the counter reset value CRV1 reflecting the digital value.

For instance, for example, when the digital value RS_D corresponding to the reference signal RS is “+1” and the digital reset signal DRS_D is “+4”, the filter 152-1 may subtract “1” from the digital reset signal to generate the counter reset value CRV1 of “+3” corresponding to the offset of the comparator 142-1. The filter 152-1 may be omitted in other embodiments when extra noise is ignorable.

The counter reset memory 154-1 may store the counter reset value CRV1 and may transmit the counter reset value CRV1 to the first counter 144-1 according to the control of the column driver 165. The counter reset memory 154-1 may be implemented as a volatile memory or a non-volatile memory. In other embodiments, the counter reset memory 154-1 may be implemented as part of a first memory 192-1 in the buffer 190.

For example, the counter reset memory 154-1 may be a volatile memory device such as a DRAM, SRAM, or the like or a non-volatile memory device such as EEPROM, FRAM, PRAM, MRAM, a flash memory or the like.

FIG. 6 is a timing chart for explaining the operation of the ADC block 140 that removes the offset of the comparator 142-1 by generating a digital reset signal once.

Referring to FIG. 6, in a period from point t0 to point t6, the digital reset signal is generated as the output COUT of the counter 144-1 and the counter reset value CRV1 corresponding to the digital reset signal (e.g. the offset of the comparator 142-1) is generated.

In a period from point t7 to point t12, the first counter 144-1 is reset using the counter reset value CRV1 and a digital pixel signal with the offset of the comparator 142-1 removed is generated as the output COUT of the counter 144-1.

In FIG. 6, for the sake of an example, it is assumed that the reference signal generator 155 generates the reference signal RS with a digital value of “1”, the offset of the comparator 142-1 has a digital value of 3, and, therefore, at point t6 the digital reset signal has a value of the sum of the reference signal RS and the, the offset of the comparator 142-1, namely a value of “4”. Further, in FIG. 6 it is assumed that the first pixel signal PS1 has a digital value of “7”, and, therefore, at time t12 the output COUT of the counter 144-1 with the offset of the comparator 142-1 removed is “7”.

Although not shown in FIG. 4, the first ICU 141-1 may include a circuit (e.g., a switch) which changes an input of the first comparator 142-1 to have the same level as the ramp signal RAMP.

The first switch control signal C_SW1 (see FIG. 4) is at a high level in a period from point t0 to point t5. Accordingly, the first switch SW1 is short-circuited and, thus, the reference signal RS output from the reference signal generator 155 is input to the second terminal of the first comparator 142-1 during points t0 to t5.

Further, as discussed above, the ramp signal RAMP generated by the ramp signal generator 160 may be input to the first terminal of the first comparator 142-1.

The ramp signal generator 160 may generate the ramp signal RAMP such that the ramp signal RAMP decreases at a desired (or, alternatively, a predetermined) slope from point t1 to point t3. As such, the reference signal RS generated by the reference signal generator 155 may be lower than the ramp signal RAMP at point t1 and higher than the ramp signal RAMP at point t3. As described above, the level of the reference signal RS illustrated in FIG. 6 may correspond to a digital value of 1.

The first comparator 142-1 generates the first comparison signal CS1 such that the first comparison signal CS1 has a high level when the input to the second terminal thereof is higher than the ramp signal RAMP input to the first terminal thereof. Accordingly, as illustrated in FIG. 6, if the reference signal RS becomes higher than the decreasing ramp signal RAMP at point T2, the comparator 142-1 may generate the first comparison signal CS1 such that the first comparison signal CS1 is at the high level after point t2.

Ideally, the output of the first counter 144-1 should be “1” (i.e., at a high level from point t2 to point t3). However, since the first comparison signal CS1 is at the high level from point t2 to point t4 due to the offset of the comparator 142-1, the first counter output signal COUT1 has a level of “+4”.

The first counter 144-1 may be reset at point t6. The first CSU 150-1 may store the counter reset value CRV1 of “+3” from point t6 to point t7 according to the first counter output signal COUT1 at the level of “+4” and the reference signal RS at the known (or, alternatively, the predetermined) level of “+1”. The first CSU 150-1 may transmit the counter reset value CRV1 of “+3” to the first counter 144-1 according to the control of the column driver 165. The first counter 144-1 may be reset to have an initial value of “−3” according to the counter reset value CRV1 of +3 at point t7.

Points t0 to t7 may be referred to as an offset compensation operation in which the first counter 144-1 is initialized such that the output COUT of the first counter 144-1 negates the offset of the comparator 142-1 based on the counter reset value CRV1 to compensate for the offset of the comparator 142-1, and points t8 to t12 may be referred to as a pixel signal generation operation in which the output COUT of the first counter 144-1 is the digital pixel signal.

The second switch control signal C_SW2 may be at a high level after point t8. Accordingly, the second switch SW2 is short-circuited and the first pixel signal PS1 output from the first column line COL1 becomes the input of the second terminal of the first comparator 142-1.

The ramp signal generator 160 may generate the ramp signal RAMP that decreases at a desired (or, alternatively, a predetermined) slope from point t9 to point t11.

The first comparator 142-1 generates the first comparison signal CS1 at the high level in a period while the input of the second terminal thereof, i.e., the first pixel signal PS1 is higher than the ramp signal RAMP input to the first terminal thereof. Ideally, the first comparison signal CS1 should be at the high level from point t10 to point t11, but the first comparison signal CS1 is at the high level from point t10 to point t12 actually due to the offset of the comparator 142-1.

The first counter 144-1 having an initial value of −3 performs counting on the first comparison signal CS1 and finally outputs the first counter output signal COUT1 at a level of +7, which is the same as the digital value of +7 of the first pixel signal PS1 which has been assumed in the above description.

If the first pixel signal PS1 is subjected to analog-to-digital conversion without the reset operation of the first CSU 150-1, the pixel signal PS1 output as first counter output signal COUT1 will be output at an incorrect level of +10.

According to embodiments of the inventive concepts, the image sensor 100 generates a digital pixel signal taking an offset of a comparator into account, thereby removing noise in the column direction.

Referring back to FIG. 2, although the operation of the ADC block 140 corresponding to only the first column line COL1 has been described, it is substantially the same as the operation of the ADC block 140 corresponding to the other column lines COL2 through COLm.

The counter reset value CRV1 may be determined based on a digital reset signal generated a random number of times (e.g., several tens of times). The counter reset value CRV1 may be updated per frame unit (e.g., one frame) in which readout is completed with respect to all rows or each time when readout is completed with respect to some (e.g., ½) of the rows.

The buffer 190 may include first through m-th memories 192-1 through 192-m respectively connected to the first through m-th counters 144-1 through 144-m and a sense amplifier 194. The first through m-th memories 192-1 through 192-m may temporarily store digital pixel signals and then sequentially output the digital pixel signals to the sense amplifier 194 according to the control of the column driver 165. The sense amplifier 194 may sense and amplify the digital pixel signals and then output them to the ISP 220. The ISP 220 may process the digital pixel signals and may also perform compensation when a digital value generated using the reference signal RS is not 0.

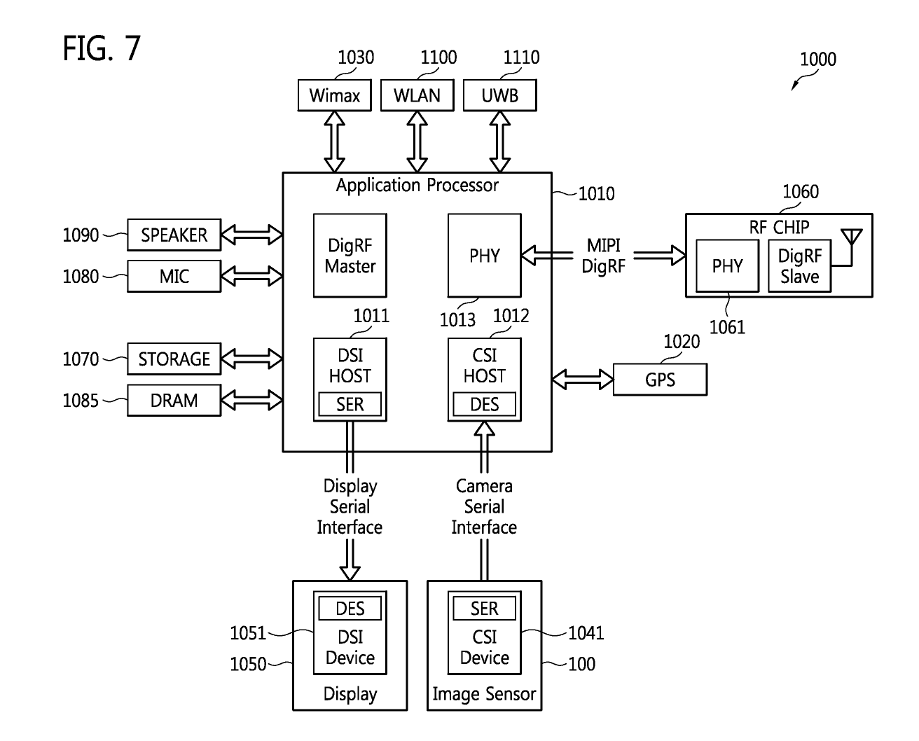

FIG. 7 is a block diagram of an electronic system including the image sensor according to some example embodiments of the inventive concepts.

Referring to FIG. 7, the electronic system 1000 may be implemented by a data processing apparatus, such as a mobile phone, a personal digital assistant (PDA), a portable media player (PMP), an IP TV, or a smart phone that can use or support the MIPI interface. The electronic system 1000 may include an application processor 1010, the image sensor 100, and/or a display 1050.

A camera serial interface (CSI) host 1012 included in the application processor 1010 performs serial communication with a CSI device 1041 included in the image sensor 100 through CSI. For example, an optical de-serializer (DES) may be implemented in the CSI host 1012, and an optical serializer (SER) may be implemented in the CSI device 1041.

A display serial interface (DSI) host 1011 included in the application processor 1010 performs serial communication with a DSI device 1051 included in the display 1050 through DSI. For example, an optical serializer may be implemented in the DSI host 1011, and an optical de-serializer may be implemented in the DSI device 1051.

The electronic system 1000 may also include a radio frequency (RF) chip 1060 which communicates with the application processor 1010. A physical layer (PHY) 1013 of the electronic system 1000 and a PHY 1061 of the RF chip 1060 communicate data with each other according to a MIPI DigRF standard. The electronic system 1000 may further include at least one element among a GPS 1020, a storage device 1070, a microphone 1080, a DRAM 1085 and a speaker 1090. The electronic system 1000 may communicate using Wimax (World Interoperability for Microwave Access) 1030, WLAN (Wireless LAN) 1100 or USB 1110, UWB (Ultra Wideband) etc.

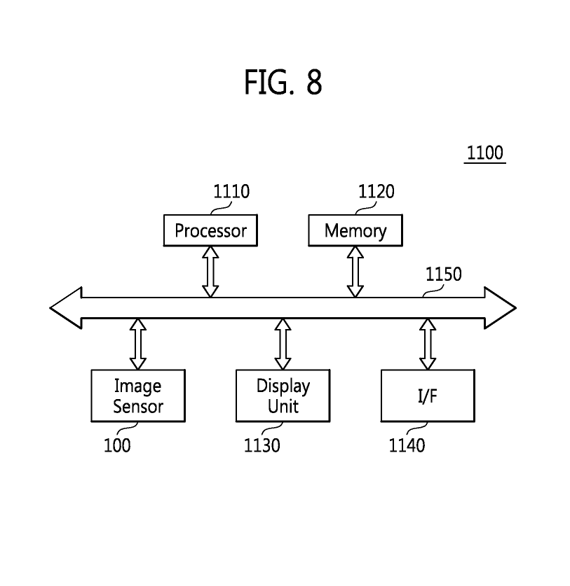

FIG. 8 is a block diagram of an image processing system 1100 including the image sensor 100 according to other example embodiments of the inventive concepts.

Referring to FIG. 8, the image processing system 1100 may include a processor 1110, a memory 1120, the image sensor 100, a display unit 1130, and an I/F 1140.

The processor 1110 may control the operation of the image sensor 100. The processor 1110 may generate a two or three dimensional image based on depth information and color information (e.g., at least one among red information, green information, blue information magenta information, cyan information, and yellow information) from the image sensor 100.

The memory 1120 may store a program for controlling the operation of the image sensor 100 through a bus 1150 according to the control of the processor 1110 and may also store the image. The processor 1110 may access the memory 1120 and execute the program. The memory 1120 may be formed as a non-volatile memory.

The image sensor 100 may generate two or three dimensional image information based on a digital pixel signal (e.g., color information or depth information) under the control of the processor 1110.

The display unit 1130 may receive the image from the processor 1110 or the memory 1120 and display the image on a display (e.g., a liquid crystal display (LCD) or an active-matrix organic light emitting diode (AMOLED) display). The I/F 1140 may be formed for the input and output of the two or three dimensional image. The I/F 1140 may be implemented as a wireless I/F.

The example embodiments of the inventive concepts can also be embodied as computer-readable codes on a non-transitory computer-readable medium. The non-transitory computer-readable recording medium is any data storage device that can store data as a program which can be thereafter read by a computer system. Examples of the computer-readable recording medium include read-only memory (ROM), random-access memory (RAM), CD-ROMs, magnetic tapes, floppy disks, and optical data storage devices.

One or more of the image signal processor 220, the timing generator 170, the reference signal generator 155 and the ramp signal generator 160 may include a processor and a memory (not shown).

The memory may contain computer readable code that, when executed by the processor, configures the processor as a special purpose computer. For example, the code may configure the image signal processor 220 as a special purpose computer to perform image processing on the image data output from the buffer 190.

Further, the analog-to-digital conversion block 140 may improve the functioning of the image sensor 100 itself by reducing or eliminating noise (e.g. fitted pattern noise (FPN)) in the image data output to the digital signal processor 200.

The computer-readable recording medium can also be distributed over network coupled computer systems so that the computer-readable code is stored and executed in a distributed fashion. Also, functional programs, codes, and code segments to accomplish the present general inventive concepts can be easily construed by programmers.

As described above, according to some example embodiments of the inventive concepts, an image sensor generates a digital pixel signal taking an offset of a comparator into account, thereby removing noise.

While example embodiments of the inventive concepts have been particularly shown and described with reference to some of the example embodiments thereof, it will be understood by those of ordinary skill in the art that various changes in forms and details may be made therein without departing from the spirit and scope of the example embodiments of the inventive concepts as defined by the following claim.

What is claimed is:

1. An image sensor comprising:
a comparator configured to compare a ramp signal input to a first terminal thereof with an input signal input to a second terminal thereof, and to generate a comparison signal based on a result of the comparison; and
a counter configured to,
generate a count according to the comparison signal, the count representing a digital pixel signal when the input signal to the comparator is a pixel signal, and
adjust the count by a counter reset value, the counter reset value being based on an offset of the comparator.

2. The image sensor of claim 1, wherein the counter is configured to generate the count such that the count represents a digital reset signal when the input signal to the comparator is a reference signal, and the image sensor further comprising:
a counter setting unit configured to generate the counter reset value based on the digital reset signal generated when the input signal to the comparator is the reference signal.

3. The image sensor of claim 2, wherein the counter setting unit comprises:
a counter reset memory configured to store the counter reset value.

4. The image sensor of claim 3, wherein the counter is configured to repeatedly generate the digital reset signal, and the counter setting unit further comprises:
a filter configured to perform filtering on the digital reset signal generated repeatedly.

5. The image sensor of claim 4, wherein the filter is an infinite impulse response (IIR) filter.

6. An image processing system comprising:
the image sensor of claim 2; and
an image processor configured to perform image processing on the digital pixel signal, and to perform compensation on a digital value corresponding to the reference signal if the digital value is an undesired value.

7. The image processing system of claim 6, wherein the counter reset value is updated at a desired interval.

8. An image sensor comprising:
a plurality of comparators configured to compare input signals with a ramp signal, and to generate comparison signals based on a result of the comparison, the input signals corresponding to one of pixel signals output from respective ones of first through m-th columns of a pixel array and a reference signal, where “m” is an integer greater than or equal to 2; and
a plurality of counters each configured to generate a count according to the comparison signal, and adjust the count by a counter reset value, the count representing a digital pixel signal when the input signals to the comparators are the pixel signals, and the counter reset value being based on offsets of respective ones of the comparators such that the counter reset value input to one of the counters is different from the counter reset value input to another one of the counters.

9. The image sensor of claim 8, wherein the counters are configured to generate the count such that the counts represent digital reset signals when the input signal to the comparators is the reference signal, and the image sensor further comprising:
a plurality of counter setting units each configured to generate a respective one of the counter reset values based on respective ones of the digital reset signals generated when the input signal to the comparators is the reference signal.

10. The image sensor of claim 9, wherein the counter setting units each comprise:
a counter reset memory configured to store respective ones of the counter reset values.

11. The image sensor of claim 10, wherein the counters are configured to repeatedly generate the digital reset signals, and the counter setting units further comprise:
a filter configured to perform filtering on respective ones of the digital reset signals generated repeatedly.

12. The image sensor of claim 11, wherein the filter is an infinite impulse response (IIR) filter.

13. An image processing system comprising:
the image sensor of claim 9; and
an image processor configured to perform image processing on the digital pixel signal, and to perform compensation on a digital value corresponding to the reference signal if the digital value is an undesired value.

14. The image processing system of claim 13, wherein the counter reset value is updated at a desired interval.

15. The image processing system of claim 14, wherein the desired interval is determined based on a frame.

16. An image sensor comprising:
a pixel array configured to output a pixel signal from a column thereof; and
an analog-to-digital converter (ADC) including,
a comparator configured to generate a comparison signal by comparing a ramp signal with an input signal,
a counter configured to generate a count based on the comparison signal, and to adjust the count based on an offset of the comparator determined while the input signal to the comparator is a reference signal, and
at least one switch configured to selectively output one of the reference signal and the pixel signal as the input signal to the comparator.

17. The image sensor of claim 16, wherein the counter is configured to adjust the count by a counter reset value, the counter reset value being adjusted once per frame until an absolute value of the counter reset value is a same as an absolute value of the offset of the comparator.

18. The image sensor of claim 17, wherein the counter is configured to repeatedly generate the count once per frame, the count representing a digital reset signal when the input signal to the comparator is the reference signal, and the counter setting unit further comprises:
a filter configured to perform filtering on the digital reset signal.

19. The image sensor of claim 18, wherein the image sensor further comprises:
a counter setting unit configured to generate the counter reset value based on the digital reset signal.

20. The image sensor of claim 16, wherein analog correlated double sampling (CDS) is performed on the pixel signals to remove noise therein prior to inputting the pixel signals as the input signal to the comparator, and
the counter is configured to output the count such that, when the input signal to the comparator is the pixel signal, the count represents a digital version of the pixel signal with the offset of the comparator removed therefrom.
